(19) United States
(12) Patent Application Publication
(10) Pub. No.: US 2007/0155078 A1
(43) Pub. Date: Jul. 5, 2007

(54) SEMICONDUCTOR DEVICE AND METHOD FOR MANUFACTURING THE SAME

(76) Inventors: Sung Ho Kwak, Seoul (KR); Sung Moo Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/614,697

(22) Filed: Dec. 21, 2006

(30) Foreign Application Priority Data
Dec. 30, 2005 (KR) 10-2005-0134898

(51) Int. Cl. H01L 21/8234; H01L 21/336; H01L 21/425

(52) U.S. Cl. 438/197; 438/527; 438/301; 438/291; 438/290

(57) ABSTRACT

A semiconductor device including at least one of: lightly doped drain regions over a semiconductor substrate; a gate insulating layer over a semiconductor substrate between lightly doped drain regions; and/or a gate formed at an upper side of a gate insulating layer. A lower width of a gate may be less than an interval between lightly doped drain regions. An upper width of a gate may be greater than an interval between lightly doped drain regions.

The present application claims priority under 35 U.S.C. 119 and 35 U.S.C. 365 to Korean Patent Application No. 10-2005-0134898 (filed on Dec. 30, 2005), which is hereby incorporated by reference in its entirety.

### BACKGROUND

In aspects of semiconductor technology, miniaturization and/or high integration technology may reduce costs, reduce manufacturing time, reduce energy, and/or improve functions of a semiconductor device. Photolithography may be a necessary manufacturing process to implement miniaturization and/or high integration of semiconductor devices.

Photolithography used in a semiconductor manufacturing process may be a projection-printing (e.g. a stepper), which may transfer light to a wafer coated with a photo resist liquid. Light may be transferred through a plurality of lenses to expose and pattern a photo resist liquid only at predetermined areas of a wafer. A resolution R of a stepper may be governed by optical diffraction represented by the Rayleigh equation. The basic Rayleigh equation is R=k1(λ/NA), where, λ is a wavelength of light, NA is a numerical aperture of a lens, and k1 is a constant representing physical aspects of a photo resist liquid. A theoretical limit of optical diffraction may be represented by NA=D/2f, where D is a diameter of a lens and f is a focus length.

Optical diffraction may also be limited by the wavelength of light used. It may be possible to overcome limitations of optical diffraction by using non-photolithography methods. It may be possible to overcome limitations of optical diffraction using soft X-ray lithography, extreme ultraviolet lithography (EUV), and/or electron beam writing.

It may be expensive to use soft X-ray lithography, extreme ultraviolet lithography (EUV), and/or electron beam writing to obtain a resolution less than 100 nm. A source used for soft X-ray lithography, extreme ultraviolet lithography (EUV), and/or electron beam writing may cause radioactive leakage, which may be damaging to the environment. In soft X-ray lithography, extreme ultraviolet lithography (EUV), and/or electron beam writing patterning may be relatively difficult on non-flat surfaces.

### SUMMARY

Embodiments relate to a semiconductor device and/or a method for manufacturing a semiconductor device which may form a gate of the semiconductor device at a relatively small resolution. In embodiments, a polymer and an impurity of a conductivity type opposite to that of the polymer may be implanted in the semiconductor device.

Embodiments relate to a method of manufacturing a semiconductor device. In embodiments, a method may include at least one of: forming an insulating layer over a silicon substrate; forming a first photo resist pattern over a insulating layer; performing a first ion implantation process using a first photo resist pattern as a mask to form lightly doped drain regions; forming a polymer around a first photo resist pattern to expose an insulating layer to a predetermined width in order to form an opening; etching an insulating layer exposed by an opening using a first photo resist pattern and a polymer as a mask; performing a second ion implantation process using impurities of a conductivity type opposite to that of the first ion implantation process by using a first photo resist pattern and a polymer as a mask; forming a gate insulating layer and a poly silicon layer over a surface of the silicon substrate; forming a second photo resist pattern over a poly silicon layer; and/or etching a poly silicon layer using a second photo resist pattern as a mask.

Embodiments relate to a semiconductor device including at least one of: lightly doped drain regions over a semiconductor substrate; a gate insulating layer over a semiconductor substrate between lightly doped drain regions; and/or a gate formed at an upper side of a gate insulating layer. A lower width of a gate may be less than an interval between lightly doped drain regions. An upper width of a gate may be greater than an interval between lightly doped drain regions.

### BRIEF DESCRIPTION OF THE DRAWINGS

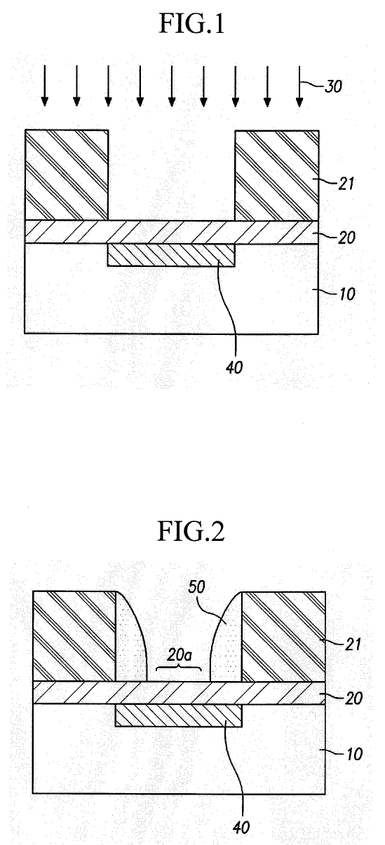

Example FIGS. 1 through 6 are views illustrating a semiconductor device and a method for manufacturing the same, according to embodiments.

### DETAILED DESCRIPTION

As illustrated in FIG. 1, insulating layer 20 may be formed over silicon substrate 10. A photolithography process may be carried out to form first photo resist pattern 21. First photo resist patter 21 may be used to form a lightly doped drain (LDD).

Insulating layer 20 may be coated with a photo resist liquid. Photo resist liquid may be exposed to light by an exposure device for form first photo resist pattern 21. Photo resist liquid may be exposed to light with a resolution capable of forming minimum pattern of first photo resist pattern 21. First ion implantation process 30 may be performed using first photo resist pattern 21 as a mask to form LDD region 40.

As illustrated in FIG. 2, polymer 50 may be formed around first photo resist pattern 21 to form opening 20a, in accordance with embodiments. Opening 20a may expose insulating layer 20 and may have a predetermined width. Polymer 50 may be formed using a mixing gas including carbon C and/or fluorine F. Polymer 50 may be produced by etch equipment capable of etching and polymer deposition. Etch equipment used to form polymer 50 may be the same as etch equipment used to form first photo resist pattern 21.

Etch equipment may simultaneously deposit polymer and etch polymer to form polymer 50 around first photo resist pattern 21. Deposited polymer may be etched to form polymer 50, which has opening 20a that exposes a portion of insulating layer 20 to have a predetermined width. Deposited polymer may be etched, such that substantially no remnants of the deposited polymer are present on insulating layer 20 at opening 20a.

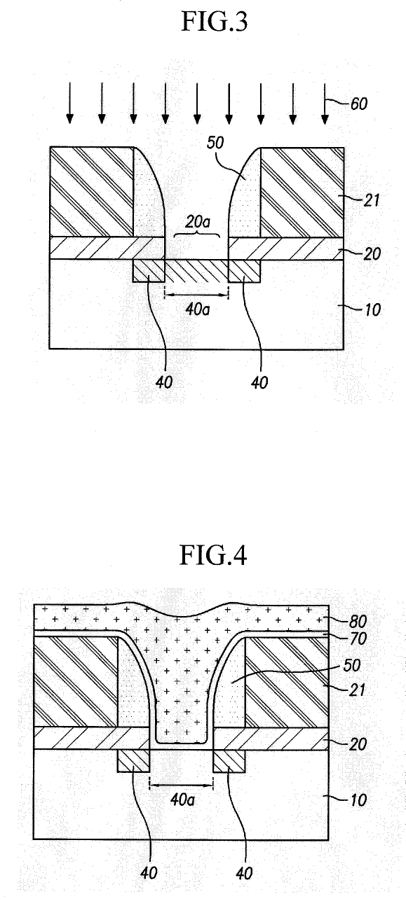

As illustrated in FIG. 3, a portion of insulating layer 20 that is exposed through opening 20a may be etched using first photo resist pattern 21 and polymer 50 as a mask, in accordance with embodiments. Insulating layer 20 may be etched by the same etch equipment that produced polymer 50, in accordance with embodiments.

A portion of insulating layer 20 that may be exposed through opening 20a may be smaller than a portion of insulating layer 20 that would be exposed if polymer 50 was not formed. In embodiments, because first photo resist pattern 21 and the polymer 50 are both used as an etch mask to etch insulating layer 20, a pattern etched in insulating layer 20 may be relatively small. If a pattern etch in insulating layer 20 is relatively small, a photolithography process may produce patterns with small widths.

Second ion implantation process 60 may be performed using the first photo resist pattern 21 and the polymer 50 to form the LDD region 40a, in accordance with embodiments. Second ion implantation process 60 may use impurities of a conductivity type opposite of first ion implantation process 30. In embodiments, if second ion implantation process 60 uses impurities of a conductivity type opposite for first ion implantation process 30, then LDD region 40a may have substantially the same ionization state that substrate 10 had before first ion implantation process 30.

As illustrated in FIG. 4, gate insulating layer 70 may be formed over substrate 10. Gate insulating layer 70 may be formed by chemical vapor deposition (CVD), in accordance with embodiments. A CVD process may be performed at a temperature less than 200° C. If gate insulating layer 70 is formed by CVD at a temperature less than 200° C., burning may not occur in photo resist pattern 21 and polymer 50.

Poly silicon layer 80 may be formed over gate insulating layer 70, in accordance with embodiments. Poly silicon layer 80 may be formed by a low temperature CVD process. In embodiments, poly silicon layer 80 may be bent due to step coverage of insulating layer 20.

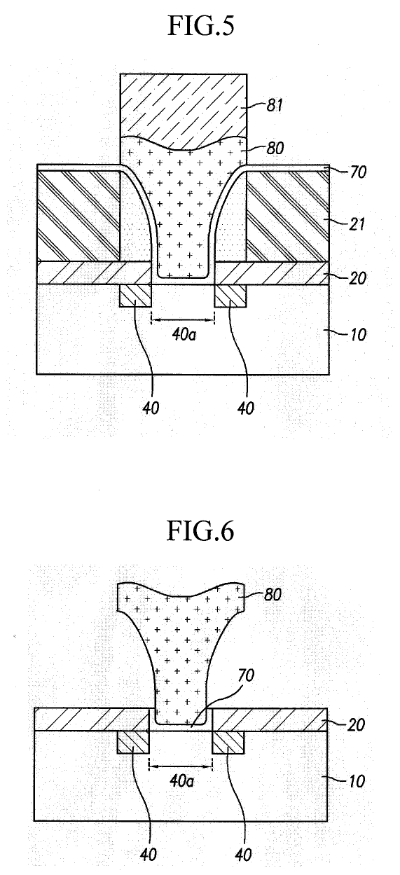

As illustrated in FIG. 5, second photo resist pattern 81 may be formed over substrate 10 and poly silicon layer 80, in accordance with embodiments. Distribution of second photo resist pattern 81 may be opposite of first photo resist pattern 21, to cover LDD region 40. Second photo resist pattern 81 may be a negative photo resist material, which may use a mask used to form first photo resist pattern 21. In embodiments, if the same mask can be used for photo resist pattern 21 and photo resist pattern 81, the number of masks may be reduced, which may minimize costs.

Poly silicon layer 80 may be etched using second photo resist pattern 81 as a mask to form gate 80. Gate 80 may have a pattern width less than the minimum pattern of the exposure equipment used. Gate 80 may be formed to have a size less than a resolution of a photolithography process used. In embodiments, if gate 80 has an upper portion having a relatively wide width (e.g. having a T-shape), a surface area of a gate may relatively large, which may minimize gate resistance. A general logic process may performed to form a semiconductor device, in accordance with embodiments.

As illustrated in FIG. 6, after formation of gate 80, gate insulating layer 70, first photo resist pattern 21, and polymer 50 formed on the sides of gate 80 may be removed. Additional processes for forming source/drain, an insulating layer, and/or an inter layer dielectric may be performed to form a semiconductor device.

In embodiments, by using a polymer and impurities having a conductivity type opposite to that of source/drain regions, a gate of a semiconductor device may be formed to have a resolution less than the resolution of a photolithography process. In embodiments, because an upper portion of a gate has a relatively wide width compared to a lower portion (e.g. a gate has a T-shape), a surface area of the gate may be relatively large, which may minimize gate resistance.

In embodiments, a costly high resolution photolithography may be unnecessary, as a gate may be formed at a relatively high resolution using a relatively low resolution photolithography process. In embodiments, manufacturing costs of a device may be minimized.

It will be apparent to those skilled in the art that various modifications and variations can be made to embodiments. Thus, it is intended that embodiments cover modifications and variations thereof within the scope of the appended claims.

What is claimed is:

1. A method comprising:
ionizing a region of a semiconductor substrate with ions of a first conductivity type;
ionizing a center portion of the region with ions of a second conductivity type.

2. The method of claim 1, wherein the center portion of the region is substantially not ionized after said ionizing the center portion of the region.

3. The method of claim 1, wherein the center portion of the region is a channel region of a semiconductor device.

4. The method of claim 1, wherein the portions of the region outside the center portion are source and drain regions of a semiconductor device.

5. The method of claim 1, comprising forming a photo resist pattern over the semiconductor substrate, wherein said ionizing the region of the semiconductor substrate with ions of a first conductivity type uses the photo resist pattern as a mask.

6. The method of claim 5, comprising forming polymer on sidewalls of photo resist pattern, wherein said ionizing the center portion of the region of the semiconductor substrate with ions of the second conductivity type uses the polymer and the photo resist pattern as a mask.

7. The method of claim 6, wherein said forming the polymer a mixing gas comprising at least one of carbon and fluorine.

8. The method of claim 6, comprising forming a gate insulating layer over the polymer and the semiconductor substrate.

9. The method of claim 8, wherein the gate insulating layer is formed by chemical vapor deposition performed at a temperature less than approximately 200° C.

10. The method of claim 1, wherein the width of a channel region formed in the semiconductor substrate is smaller than the resolution of a photolithography process used to form the channel region.

11. An apparatus comprising:
a first ionized region of a semiconductor substrate with ions of a first conductivity type;
a second ionized region of the semiconductor substrate which overlaps with the first ionized region, wherein the second ionized region is in the center of the first ionized region and the second ionized region is ionized with ions of a second conductivity type.

12. The apparatus of claim 11, wherein the second ionized region is substantially not ionized because ions of the second conductivity type substantially neutralize ions the first conductivity type.

13. The apparatus of claim 11, wherein the center portion of the first ionized region is a channel region of a semiconductor device.

14. The apparatus of claim 11, wherein portions of the first ionized region that do not overlap the second ionized region are source and drain regions of a semiconductor device.

15. The appparatus of claim 11, comprising forming a photo resist pattern over the semiconductor substrate, wherein said ionizing the region of the semiconductor substrate with ions of a first conductivity type uses the photo resist pattern as a mask.

16. The apparatus of claim 15, wherein the second ionized region is formed by forming polymer on sidewalls of photo resist pattern, wherein said ionizing the second ionized region uses the polymer and the photo resist pattern as a mask.

17. The apparatus of claim 16, wherein forming the polymer uses a mixing gas comprising at least one of carbon and fluorine.

18. The apparatus of claim 16, wherein a gate insulating layer is formed over the polymer and the semiconductor substrate.

19. The apparatus of claim 18, wherein the gate insulating layer is formed by chemical vapor deposition performed at a temperature less than approximately 200° C.

20. The apparatus of claim 11, wherein the width of a channel region formed in the semiconductor substrate is smaller than the resolution of a photolithography process used to form the channel region.
